(19) United States
(12) Patent Application Publication
(10) Pub. No.: US 2014/0160271 A1
(43) Pub. Date: Jun. 12, 2014

(54) DETECTION SYSTEM AND METHOD

(71) Applicant: HON HAI PRECISION INDUSTRY CO., LTD., New Taipei (TW)

(72) Inventors: SZU-LUN HUANG, New Taipei (TW); CHIH-HUANG WU, New Taipei (TW)

(73) Assignee: HON HAI PRECISION INDUSTRY CO., LTD., New Taipei (TW)

(21) Appl. No.: 14/085,927

(22) Filed: Nov. 21, 2013

(30) Foreign Application Priority Data
Dec. 7, 2012 (TW) 101146284

(51) Int. Cl. G06T 7/00; G01R 31/28

(52) U.S. Cl. CPC G06T 7/001; G01R 31/2801
USPC 348/87; 382/147

(57) ABSTRACT

A detection system and method for detecting if of a plurality of electrical elements on a printed circuit board (PCB) is loaded inversely are provided. The system includes a setting module to receive a standard image of a standard PCB and select one or more of the electrical elements from the standard image by a user. A storage module stores a reference image. A capturing module captures an image of the PCB to be detected. A comparison module compares the image with the reference image to determine if any of the electrical elements having polarities is inversely loaded. A processing module reads a comparison result of the comparison module and makes a determination.

### BACKGROUND

1. Technical Field

The present disclosure relates to detection systems and methods, and particularly to a detection system and method for detecting whether or not any electrical element having polarities is loaded inversely on a printed circuit board.

2. Description of Related Art

If electrical elements having polarities, such as electrolytic capacitors, are loaded inversely on printed circuit boards (PCBs), the PCBs may not work properly or be damaged in use. Therefore, it is necessary to detect whether any electrical element having polarities are loaded inversely before use. Currently, this detection is performed manually, which is insufficient.

Therefore, it is desirable to provide a detection system and method to eliminate this problem.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure.

FIG. 1 is a functional block diagram of one embodiment of a detection system for detecting whether or not any electrical element having polarities is loaded inversely on a printed circuit board.

FIG. 2 is a first schematic view showing how to operate the system of FIG. 1

FIG. 3 is a second schematic view showing how to operate the system of FIG. 1.

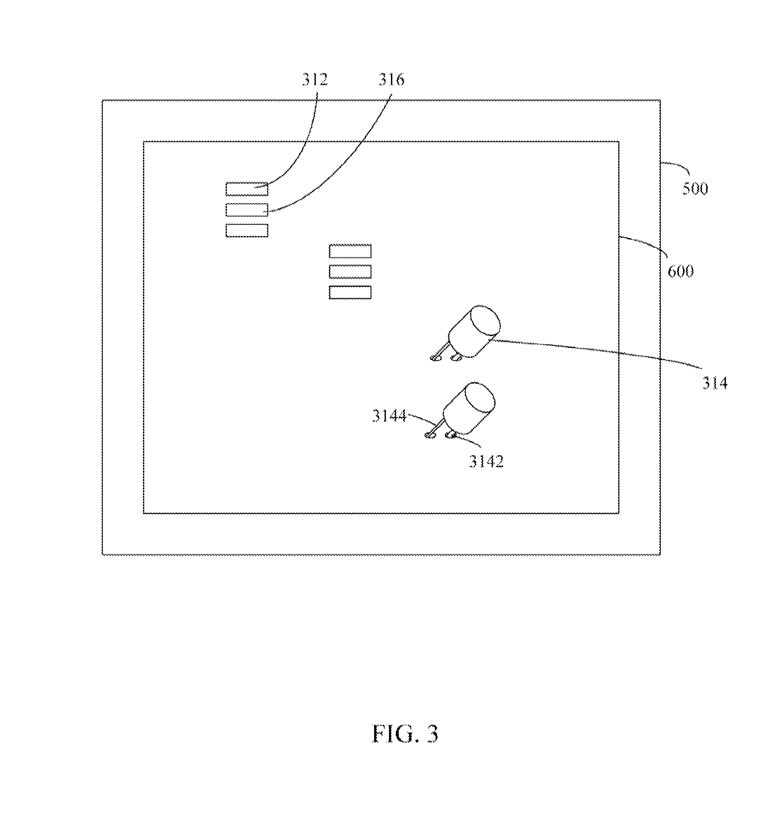

FIG. 4 is a flowchart of one embodiment of a method for detecting whether any electrical element having polarities is loaded inversely on a printed circuit board.

### DETAILED DESCRIPTION

Embodiments of the present disclosure will be described with reference to the drawings.

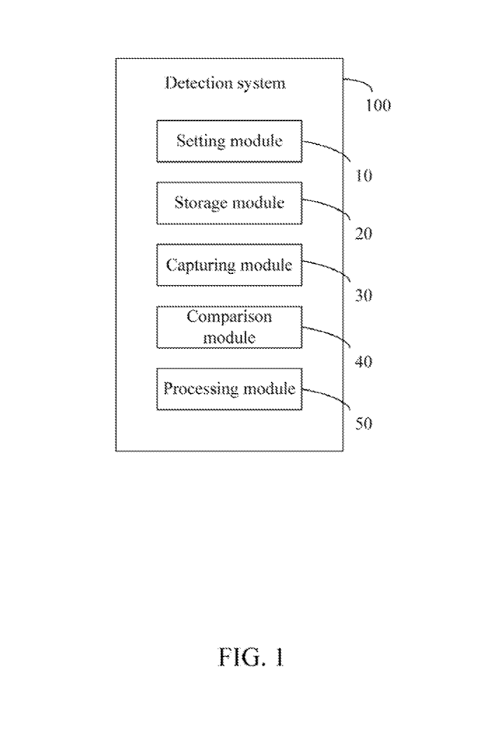

FIG. 1 shows one embodiment of a detection system 100 for detecting whether any electrical element on a printed circuit board (PCB) is loaded inversely, i.e., polarities of the electrical element are inverted. The system 100 is performed by software, including a setting module 10, a storage module 20, a capturing module 30, a comparison module 40, and a processing module 50.

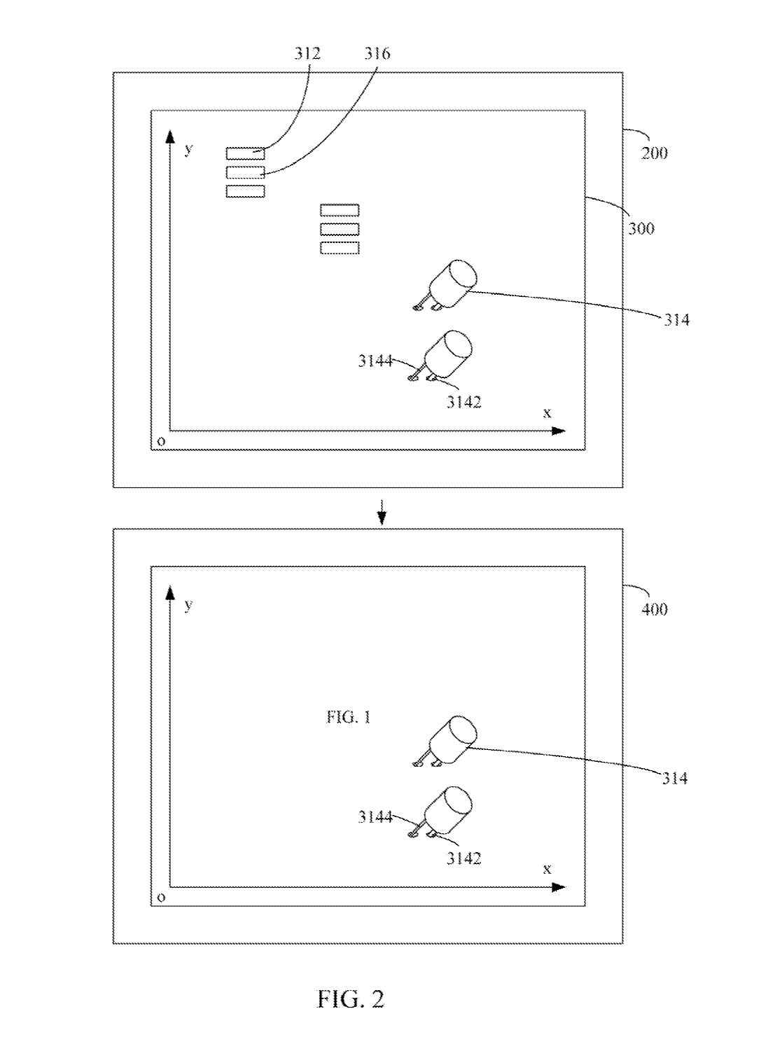

FIG. 2 shows that the setting module 10 is configured to receive a standard image 200 of a standard PCB 300. The standard image 300 shows a coordinate system and a number of electrical elements, such as resistors 312, electrolytic capacitors 314, and inductors 316, located within the coordinate system. The setting module 10 is configured to select one or more of the electrical elements from the standard image 200 by a user, such as the electrolytic capacitors 314, as targets in response to user inputs, and generate a reference image 400. In the reference image 400, the electrolytic capacitors 314 are shown and a positive electrode 3142 and a negative electrode 3144 of the electrolytic capacitors 314 can be easily distinguished by their appearance, including shape, size, and color.

In other embodiments, the targets can be a diode, a tantalum capacitor, or other electrical elements having polarities.

The storage module 20 is configured to store the reference image 400.

The capturing module 30 is configured to capture an image 500 of a PCB 600 to be detected. In this embodiment, the capturing module 30 is a camera module installed in a production line of the PCB 600.

The comparison module 40 is configured to compare the image 500 with the reference image 400 to determine if any electrical element having polarities is inversely loaded. The comparison module 40 recognizes the electrolytic capacitors 314 by coordinate values thereof and mode recognition technology. The comparison module 40 then compares the shape, size, and color of each of the positive electrode 3142 and the negative electrode 3144 with the corresponding positive electrode 3142 and negative electrode 3144 in the reference image 400.

The processing module 50 is configured to read comparison results of the comparison module 40 and make a determination. If the shape, size, and color of each of the positive electrode 3142 and the negative electrode 3144 in the image 500 with the corresponding positive electrode 3142 and negative electrode 3144 in the reference image 400 are different, the electrolytic capacitor 314 is loaded inversely and needs to be reassembled. Otherwise, the electrolytic capacitor 314 is loaded correctly and passes the detection.

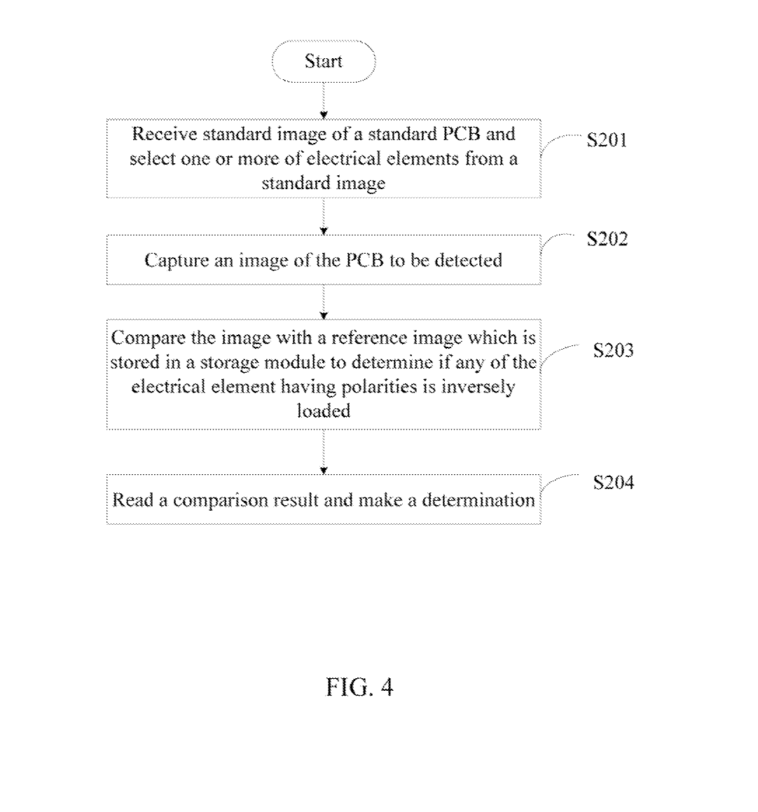

FIG. 4 is a flowchart of one embodiment of a method for detecting if any electrical element having polarities is loaded inversely on a printed circuit board.

In step S201, the setting module 10 receives the standard image 200 of the standard PCB 300, and selects one or more of the electrical elements from the standard image 200 by the user.

In step S202, the capturing module 30 captures an image 500 of the PCB 600 to be detected.

In step S203, the comparison module 40 compares the image 500 with the reference image 400 stored in the storage module 20 to determine if any electrical element having polarities is loaded inversely.

In step S204, the processing module 50 reads comparison result of the comparison module 40 and makes the determination.

It will be understood that the above particular embodiments are shown and described by way of illustration only. The principles and the features of the present disclosure may be employed in various and numerous embodiments thereof without departing from the scope of the disclosure. The above-described embodiments illustrate the possible scope of the disclosure but do not restrict the scope of the disclosure.

What is claimed is:

1. A detection system for detecting if any of a plurality of electrical elements on a printed circuit board (PCB) is loaded inversely, the detection system comprising:
a setting module to receive a standard image of a standard PCB and select one or more of the electrical elements from the standard image by a user;
a storage module to store a reference image;
a capturing module installed in a production line of the PCB to capture an image of the PCB to be detected;
a comparison module to compare the image with the reference image and determine if any of the electrical elements is inversely loaded; and
a processing module to read a comparison result of the comparison module and make a determination.

2. The detection system of claim 1, wherein the standard image comprises a coordinate system and a number of the electrical elements, the setting module selects one or more of the electrical elements to be detected as targets in response to user inputs, and generates the reference image.

3. The detection system of claim 2, wherein the target is a diode, a tantalum capacitor, or an electrical element having polarities.

4. The detection system of claim 2, wherein the comparison module recognizes the electrical elements by coordinate values and mode recognition technology, compares a shape, size, and color of each of a positive electrode and a negative electrode with a corresponding positive electrode and a corresponding negative electrode in the reference image; when the shape, size, and color of the each of the positive electrode and the negative electrode in the image with the corresponding positive electrode and negative electrode in the reference image are different, the electrolytic element is loaded inversely, otherwise, the electrolytic element is loaded correctly.

5. The detection system of claim 1, wherein the capturing module is a camera module.

6. A detection method for detecting if any of a plurality of electrical elements on a printed circuit board (PCB) is loaded inversely, the detection method comprising:
receiving a standard image of a standard PCB and selecting one or more of the electrical elements from the standard image by a user;
capturing an image of the PCB to be detected;
comparing the image with a reference image and determine if any of the electrical elements having polarities is inversely loaded; and
reading a comparison result of the comparison module and making a determination.

7. The detection method of claim 6, wherein the standard image comprises a coordinate system and a number of the electrical elements, the method further comprises selecting one or more of the electrical elements to be detected as targets in response to user inputs, and generating the reference image.

8. The detection method of claim 7, wherein the target is a diode, a tantalum capacitor, or an electrical element having polarities.

9. The detection method of claim 7, wherein the method of comparing the image with a reference image and determine if any of the electrical elements having polarities is inversely loaded and reading a comparison result of the comparison module and making a determination further comprising: recognizing the electrical elements by coordinate values and mode recognition technology, comparing a shape, size, and color of each of a positive electrode and a negative electrode with a corresponding positive electrode and a corresponding negative electrode in the reference image; when the shape, size, and color of the each of the positive electrode and the negative electrode in the image with the corresponding positive electrode and negative electrode in the reference image are different, the electrolytic element is loaded inversely, otherwise, the electrolytic element is loaded correctly.

10. The detection method of claim 7, wherein the method of capturing an image of the PCB to be detected is performed by a camera module installed in a production line of the PCB.
